(19) United States
(12) Patent Application Publication
(10) Pub. No.: US 2015/0071005 A1
(43) Pub. Date: Mar. 12, 2015

(54) NONVOLATILE SEMICONDUCTOR MEMORY DEVICE

(71) Applicant: KABUSHIKI KAISHA TOSHIBA, Tokyo (JP)

(72) Inventors: Hiroshi MAEJIMA, Setagaya (JP); Yoshihiko KAMATA, Yokohama (JP)

(73) Assignee: KABUSHIKI KAISHA TOSHIBA, Tokyo (JP)

(21) Appl. No.: 14/192,380

(22) Filed: Feb. 27, 2014

(30) Foreign Application Priority Data
Sep. 11, 2013 (JP) 2013-188840

(51) Int. Cl. G11C 16/28

(52) U.S. Cl. CPC G11C 16/28
USPC 365/185.21

(57) ABSTRACT

A NAND type flash memory includes a plurality of memory cells, a bit line electrically connected to a first end of the memory cells, a source line electrically connected to a second end of the memory cells, and a control unit configured to carry out one of first and second sense operations, the first sense operation being carried out when a first read command is received and the second sense operation being carried out when a second read command is received, the first read command being different from the second read command.

### CROSS-REFERENCE TO RELATED APPLICATION

This application is based upon and claims the benefit of priority from Japanese Patent Application No. 2013-188840, filed Sep. 11, 2013, the entire contents of which are incorporated herein by reference.

### FIELD

Embodiment described herein relates generally to a nonvolatile semiconductor memory device, for example, a NAND type flash memory.

### BACKGROUND

In the related art, a memory such as a stacked NAND flash memory in which memory cells are stacked, e.g., bit-cost scalable (BiCS) flash memory, is used for improving a bit density of a NAND type flash memory.

The BiCS flash memory employs a fast reading operation in order to read data at a high speed even if an error rate slightly increases as compared with a normal reading operation.

### DESCRIPTION OF THE DRAWINGS

FIG. 1 is a block diagram illustrating a memory system according to a present embodiment.

FIG. 2 is a block diagram illustrating an example of a NAND type flash memory illustrated in FIG. 1.

FIG. 3 is a circuit diagram illustrating an example of the NAND type flash memory illustrated in FIG. 1.

FIG. 4 is a circuit diagram illustrating an example of a sense amplifier employed in the present embodiment.

FIG. 5 illustrates waveform diagrams depicting different operations of the sense amplifier.

FIG. 6 is a waveform diagram illustrating an example of a reading operation of a memory cell according to the present embodiment.

FIG. 7 is a waveform diagram illustrating another example of the reading operation of the memory cell according to the present embodiment.

FIGS. 8A to 8C are diagrams illustrating different examples of a reading sequence.

FIG. 9 is a waveform diagram illustrating an operation timing in source bias ABL sense.

FIG. 10 is a waveform diagram illustrating an operation timing in source VSS ABL sense.

FIG. 11 is a perspective view illustrating a first example of a three-dimensional stacked NAND string.

FIG. 12 is a perspective view illustrating a second example of a three-dimensional stacked NAND string.

FIG. 13 is a waveform diagram illustrating an operation timing of the NAND string illustrated in FIG. 12.

FIG. 14 is a perspective view illustrating a third example of a three-dimensional stacked NAND string.

### DETAILED DESCRIPTION

The present exemplary embodiment provides a nonvolatile semiconductor memory device capable of further reducing a reading time in a fast reading operation.

In general, according to one embodiment, a nonvolatile semiconductor memory device includes a plurality of memory cells, a bit line electrically connected to a first end of the memory cells, a source line electrically connected to a second end of the memory cells, and a control unit configured to carry out one of first and second sense operations, the first sense operation being carried out when a first read command is received and the second sense operation being carried out when a second read command is received, the first read command being different from the second read command.

The present embodiment relates to a NAND type flash memory, and particularly to a fast reading operation in BiCS flash memory. A fast reading operation is a mode used when data is required to be read at a high speed even if accuracy (error rate) slightly deteriorates as compared with a normal reading operation. In BiCS flash memory, all bit line (ABL) sense of sensing potentials of all bit lines is used in a normal reading or verification operation, and a source line is precharged to a positive voltage of 0 V or higher, and the source line is continuously biased by a regulator (hereinafter, this sense method is referred to as source bias ABL sense), thereby suppressing noise of the source line. However, the source bias ABL sense has a problem in that a wasteful time is taken to precharge the source line.

Generally, the method of biasing the source line to a positive voltage of 0 V or higher has the following two merits.

(1) In a case of a floating gate NAND type flash memory, a memory cell in an erasure state is set to a negative threshold voltage, and thus the negative threshold voltage can be read.

(2) Noise of the source line can be reduced. In other words, it is possible to suppress a voltage drop (IR drop) due to On resistance of a driver and a resistive component of a power line connected between the driver and pads.

However, in a charge trap type memory cell such as BiCS flash memory, a threshold value after erasure is located on a positive side, and thus a negative threshold voltage is not required to be read. For this reason, as in the fast reading operation, if sacrifice of accuracy (error rate) is possible, noise of the source line is not required to be improved in (2), and the source line is not required to be biased to a positive voltage of 0 V or higher.

Therefore, in the present exemplary embodiment, in a fast reading operation, a source line is not biased to a positive voltage but is set to 0 V, or a level of the source line is set to be lower than in normal reading, thereby reducing a reading time.

In addition, in the fast reading operation, not only a method of employing ABL type sense but also a method of employing bit line shield type sense is proposed.

Hereinafter, an embodiment will be described with reference to the drawings.

### Embodiment

The same part is given the same reference numeral throughout all the drawings.

A semiconductor memory device, a controller, and a memory system according to the present embodiment will be described. Hereinafter, the semiconductor memory device will be described using a three-dimensional stacked NAND type flash memory in which memory cells are stacked on a semiconductor substrate as an example.

### Configuration of Memory System

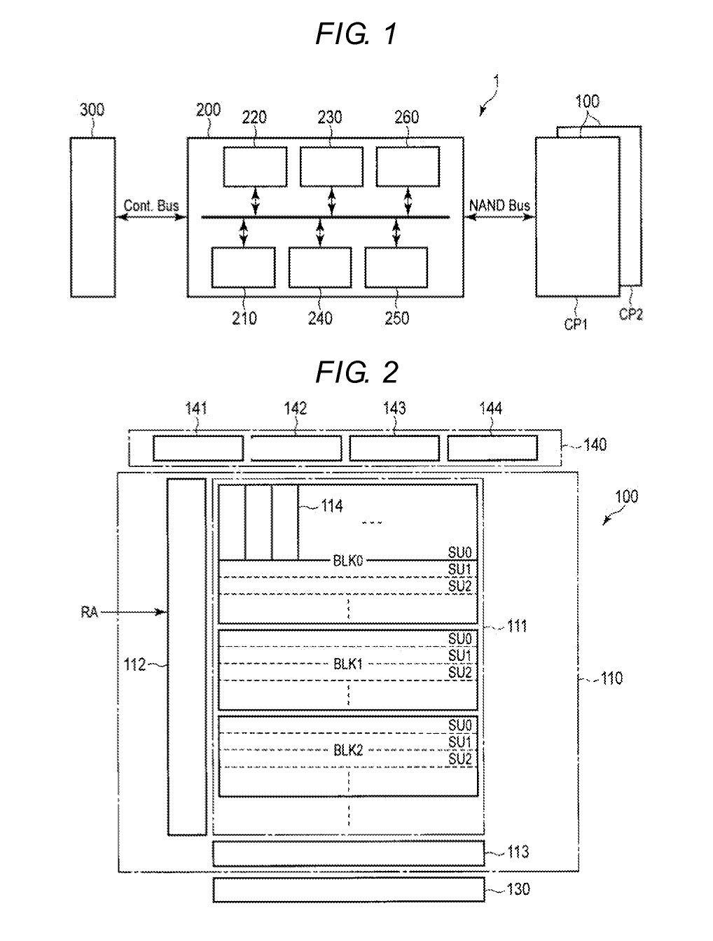

With reference to FIG. 1, a description will be made of a configuration of a memory system including a semiconductor memory device according to the present embodiment.

A memory system 1 includes a NAND type flash memory 100, a controller 200, and a host apparatus 300.

The NAND type flash memory 100 includes, for example, a plurality of chips CP1 and CP2. Each of the chips has a plurality of memory cells, and stores data in a nonvolatile manner. A configuration of the NAND type flash memory will be described later in detail.

The controller 200 commands the NAND type flash memory 100 to read, write, and erase data, and the like, in response to a command from the host apparatus 300. In addition, the controller 200 manages a memory space of the NAND type flash memory 100. The controller 200 and the NAND type flash memory 100 may form, for example, the same semiconductor device.

Further, the memory system 1 may be a single device, or the memory system 1 may be formed by, for example, a memory card such as an SD™ card, a solid state drive (SSD), or the like.

In addition, the memory system 1 may be a personal computer having the NAND type flash memory 100 and the controller 200 built therein, or may be an application having the NAND type flash memory 100 mounted therein.

The controller 200 includes a host interface circuit 210, a built-in memory (RAM) 220, a processor (CPU) 230, a buffer memory 240, a NAND interface circuit 250, and an ECC circuit 260.

The host interface circuit 210 is connected to the host apparatus 300 via a controller bus, and performs communication with the host apparatus 300. The host interface circuit 210 transmits commands and data received from the host apparatus 300 to the CPU 230 and the buffer memory 240, and transmits data in the buffer memory 240 to the host apparatus 300 in response to a command from the CPU 230.

The NAND interface circuit 250 is connected to the NAND type flash memory 100 via a NAND bus, and performs communication with the NAND type flash memory 100. The NAND interface circuit 250 transmits a command received from the CPU 230 to the NAND type flash memory 100. The NAND interface circuit 250 transmits data to be written in the buffer memory 240 to the NAND type flash memory 100 during writing of data, and transmits data read from the NAND type flash memory 100 to the buffer memory 240 during reading of data.

The CPU 230 controls an overall operation of the controller 200. For example, when a reading command is received from the host apparatus 300, the CPU 230 issues a reading command based on a NAND interface in response thereto. Also during writing and erasing of data, when writing and erasure commands are received from the host apparatus 300, the CPU 230 issues writing and erasure commands based on the NAND interface in response thereto. In addition, the CPU 230 performs various processes for managing the NAND type flash memory 100, such as wear leveling. Further, the CPU 230 performs various operations. For example, an encoding process or a randomizing process of data is performed.

The ECC circuit 260 performs a data error checking and correcting (ECC) process. In other words, the ECC circuit 260 generates parities based on data to be written during writing of data, and generates syndromes from the parities so as to check errors and to correct the errors during reading of data. In addition, the CPU 230 may have a function of the ECC circuit 260.

The built-in memory 220 is, for example, a semiconductor memory such as a DRAM, and is used as a work area of the CPU 230. The built-in memory 220 holds firmware for managing the NAND type flash memory 100, various management tables, or the like.

### Configuration of Semiconductor Memory Device

FIG. 2 is a block diagram of the NAND type flash memory 100 according to the present embodiment. The NAND type flash memory 100 includes a core unit 110, an input and output unit 130, and a peripheral circuit 140.

The core unit 110 includes a memory cell array 111, a row decoder 112, and a sense amplifier 113.

The memory cell array 111 has a plurality of (for example, N) blocks BLK (BLK0, BLK1, BLK2, . . . ) which are sets of nonvolatile memory cells. Data in a single block BLK is collectively erased. Each of the blocks BLK includes a plurality of (for example, M) string units SU (SU0, SU1, SU2, . . . ) which are sets of NAND strings 114 in which memory cells are connected in series to each other. Any number of blocks in the memory cell array 111 and any number of string units in the block may be used.

The row decoder 112 decodes a block address BA received from the controller 200 so as to select a corresponding block BLK, and applies a predetermined voltage to a word line or a selection gate line described later.

The sense amplifier 113 senses and amplifies data read from the memory cell during reading of data, and outputs the read data to the controller 200 as necessary. In addition, during writing of data, data to be written received from the controller 200 is transmitted to the memory cell. Reading and writing of data from and to the memory cell array 111 are performed in the unit of a plurality of memory cells, and this unit is a page.

The input and output unit 130 transmits and receives various commands or data to and from the controller 200 via the NAND bus.

The peripheral circuit 140 includes a sequencer 141, a charge pump 142, a register 143, and a driver 144.

The driver 144 supplies voltages required to write, read and erase data, to the row decoder 112 or the sense amplifier 113. These voltages are applied to various wires in the memory cell array 111. The charge pump 142 steps up a power supply voltage given from an external device, and supplies the stepped-up voltage to the driver 144. The register 143 holds various signals. For example, the register 143 holds a status of a data writing or erasure operation, and notifies the controller of whether or not the operation is normally completed on the basis thereof. The sequencer 141 controls an overall operation of the NAND type flash memory 100.

### Memory Cell Array 111

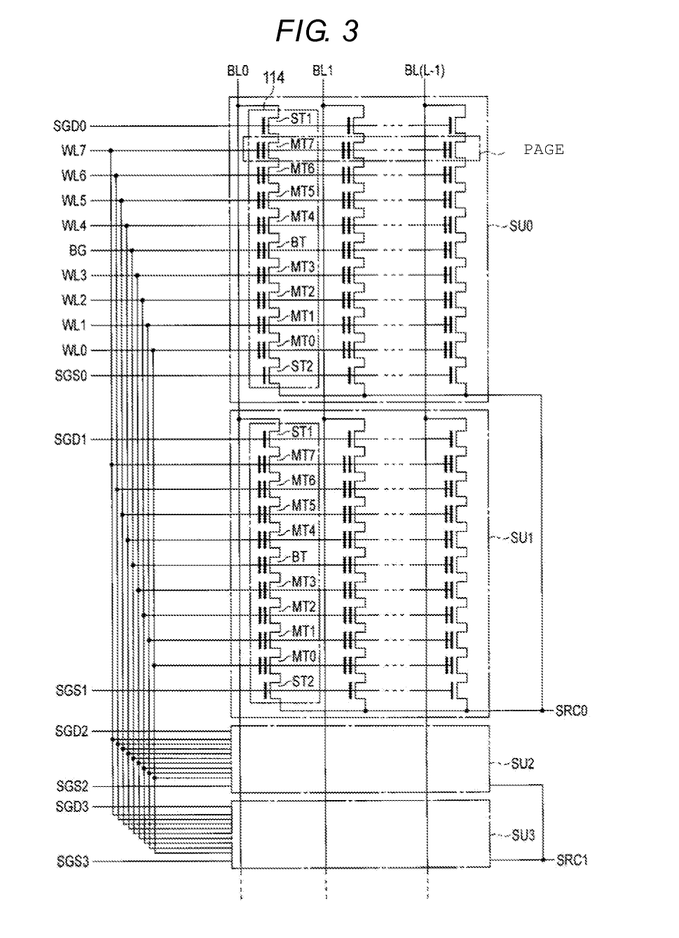

FIG. 3 is a diagram illustrating a part of the memory cell array 111, and is a circuit diagram of the block BLK0. The other blocks BLK also have the same configuration as the configuration of the block BLK0.

In FIG. 3, the block BLK0 includes a plurality of string units SU. In addition, each of the string units SU includes a plurality of (L in this example) NAND strings 114.

Each of the NAND strings 114 includes, for example, eight memory cell transistors MT (MT0 to MT7) (also referred to as memory cells MC), selection transistors (also referred to as selection gates) ST1 and ST2, and a back gate transistor BT. The memory cell transistor MT is provided with a layered gate including a control gate and a charge storage layer, and holds data in a nonvolatile manner. In addition, the number of memory cell transistors MT is not limited to eight, and may be 16, 32, 64, 128, or the like. The back gate transistor BT is also provided with a layered gate including a control gate and a charge storage layer as in the memory cell transistor MT. However, the back gate transistor BT is not used to hold data but merely functions as a current path when data is written and erased. The memory cell transistor MT and the back gate transistor BT are disposed such that a current path is connected in series between the selection transistors ST1 and ST2. In addition, the back gate transistor BT is provided between the memory cell transistors MT3 and MT4. A current path of the memory cell transistor MT7 on one end side of this series connection is connected to one end of a current path of the selection transistor ST1, and a current path of the memory cell transistor MT0 on the other end side thereof is connected to one end of a current path of the selection transistor ST2.

The gates of the selection transistors ST1 of the string units SU0 to SU(M−1) are respectively connected in common to selection gate lines SGD0 to SGD(M−1), and the gates of the selection transistors ST2 are respectively connected in common to selection gate lines SGS0 to SGS(M−1). In contrast, the control gates of the memory cell transistors MT0 to MT7 of the same block BLK0 are respectively connected in common to the word lines WL0 to WL7, and control gates of back gate transistors BT are connected in common to a back gate line BG (in the blocks BLK0 to BLK(N−1), respectively BG0 to BG(N−1)).

In other words, the word lines WL0 to WL7 and the back gate line BG are connected in common between a plurality of string units SU of the same block BLK0, whereas the selection gate lines SGD and SGS are independent for each string unit SU even in the same block BLK0.

In addition, among the NAND strings 114 which are disposed in a matrix in the memory cell array 110, the other ends of the current paths of the selection transistors ST1 of the NAND strings 114 of the same column are connected in common to any bit line BL. In other words, the bit line BL is connected in common to a plurality of NAND strings 114 in the block BLK, and is further connected in common to the NAND strings 114 of a plurality of blocks BLK. In addition, the other ends of the current paths of the selection transistors ST2 are connected to any source line SRC. The source line SRC is connected in common to the NAND strings 114, for example, in a plurality of string units SU.

As described above, data of a plurality of memory cell transistors MT in the same block BLK is collectively erased. In contrast, reading and writing of data are collectively performed on a plurality of memory cell transistors MT which are connected in common to any word line WL in any string unit SU of any block BLK. In other words, the unit in which reading and writing of data are collectively performed is called a “page”.

In the memory cell array 111 with the above-described configuration, the memory cell transistors MT, the selection transistors ST1 and ST2, and the back gate transistor BT are stacked on the semiconductor substrate in a three-dimensional manner. As an example, a part of the peripheral circuit such as a sense amplifier module is formed on the semiconductor substrate, and the memory cell array 111 is formed over the peripheral circuit.

A configuration of the memory cell array 111 is disclosed in, for example, U.S. patent application Ser. No. 12/407,403, filed on Mar. 19, 2009, entitled “three-dimensional stacked nonvolatile semiconductor memory”. In addition, a configuration thereof is disclosed in U.S. patent application Ser. No. 12/406,524, filed on Mar. 18, 2009, entitled “three-dimensional stacked nonvolatile semiconductor memory”, U.S. patent application Ser. No. 12/679,991, filed on Mar. 25, 2010, entitled “nonvolatile semiconductor memory device and manufacturing method thereof”, and U.S. patent application Ser. No. 12/532,030, filed on Mar. 23, 2009, entitled “semiconductor memory and manufacturing method thereof”. The entire contents of the above-referenced Patent Applications are incorporated by reference in the present application.

### Sense Amplifier 113

The above-described sense amplifier 113 includes a plurality of sense amplifier units SAU, and each of the sense amplifier units SAU is connected to the bit line.

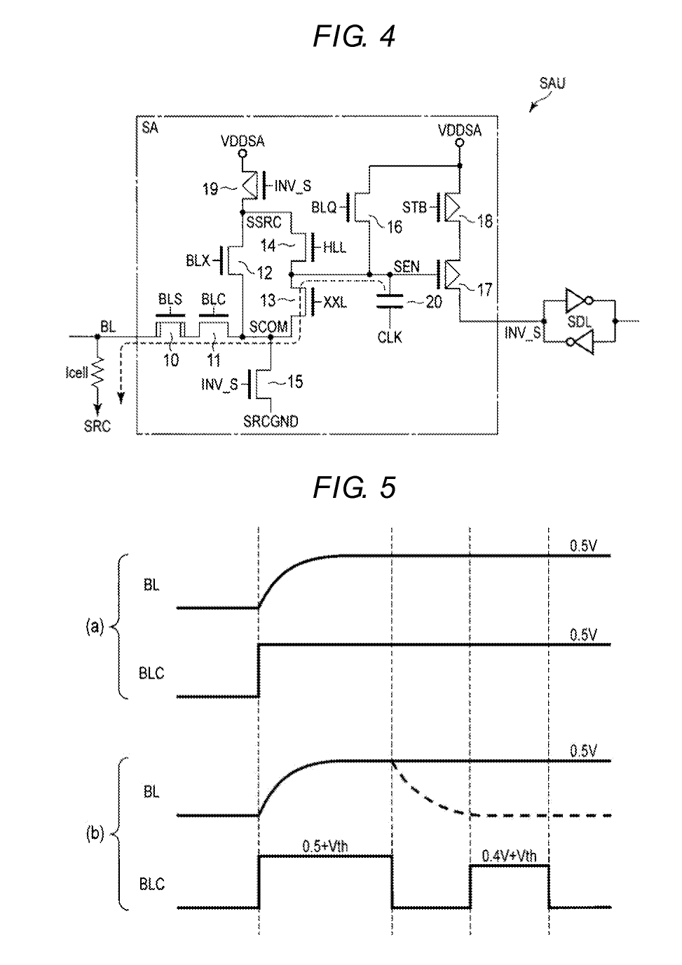

FIG. 4 illustrates an example of the sense amplifier unit SAU.

The sense amplifier unit SAU includes a sense amplifier portion SA and a latch circuit SDL. In addition, if the memory cell transistor holds data of 2 or more bits, two or more latch circuits are provided.

The sense amplifier portion SA senses and amplifies data which is read to the bit line BL, and applies a voltage to the bit line BL according to data held in the latch circuit SDL. In other words, the sense amplifier portion SA is a module which directly controls the bit line BL. The latch circuit SDL temporarily holds data. The latch circuit SDL holds data to be written as received from the controller 200 via the input and output unit 130 during writing of data. During reading of data, the latch circuit SDL holds data which is sensed and amplified by the sense amplifier portion SA, and transmits the data to the controller 200 via the input and output unit 130.

The sense amplifier portion SA includes, for example, a high breakdown voltage n channel MOS transistor 10, low breakdown voltage n channel MOS transistors 11 to 16, low breakdown voltage p channel MOS transistors 17 to 19, and a capacitor element 20. A configuration of the sense amplifier portion SA is not limited thereto, and may be modified.

The transistor 10 has a gate to which a signal BLS is applied and one end of a current path connected to a corresponding bit line BL. The transistor 11 has one end of a current path connected to the other end of the current path of the transistor 10, a gate to which a signal BLC is applied, and the other end of the current path connected to a node SCOM. The transistor 11 is used to clamp the corresponding bit line BL to a potential corresponding to the signal BLC.

The transistor 15 has one end of a current path connected to the node SCOM, the other end thereof connected to a node SRCGND (for example, 0 V), and a gate connected to a node INV_S of the latch circuit SDL. The transistor 12 has one end of a current path connected to the node SCOM, the other end thereof connected to a node SSRC, and a gate to which a control signal BLX is applied. The transistor 19 has one end of a current path connected to the node SSRC, the other end thereof to which a power supply voltage VDDSA is given, and a gate connected to the node INV_S. The transistor 13 has one end of a current path connected to the node SCOM, the other end thereof connected to a node SEN, and a gate to which a control signal XXL is input. The transistor 14 has one end of a current path connected to node SSRC, the other end thereof connected to the node SEN, and a gate to which a control signal HLL is input.

The transistor 17 has one end of a current path connected to the node INV_S of the latch circuit SDL, and a gate connected to the node SEN. The transistor 18 has one end of a current path connected to the other end of the current path of the transistor 17, the other end thereof to which the power supply voltage VDDSA is given, and a gate to which a control signal STB is input. The transistor 16 has one end of a current path connected to the node SEN, the other end thereof to which the power supply voltage VDDSA is given, and a gate to which a control signal BLQ is input. The capacitor element 20 has one electrode connected to the node SEN and the other electrode to which a clock CLK is input.

In the present embodiment, the sense amplifier 113 can perform an ABL type reading operation or a bit line shield type reading operation depending on a command. The ABL type reading operation is a current sense type reading operation, and the bit line shield type reading operation is a voltage sense type reading operation.

### ABL Type Reading Operation

With reference to (a) of FIG. 5, a description will be made of an operation of the sense amplifier portion SA in the ABL type reading operation. In addition, (a) and (b) of FIG. 5 illustrate only a relationship between potentials of the signal BLC and the bit line BL.

First, the signals BLS, BLC and BLX are turned to an “H” level, and the node INV_S of the latch circuit SDL is set to an “L” level. For this reason, the transistors 19, 12, 11 and 10 are turned on, and thus the bit line BL is precharged to a predetermined potential Vbl in the path of the transistors 19, 12, 11 and 10. In addition, the signal HLL is turned to an “H” level, and thus the capacitor element 20 is charged such that a potential of the node SEN increases.

Next, the signals BLX and HLL are turned to an “L” level, and the signal XXL is turned to an “H” level, to thereby permit sensing of data.

Here, if a threshold voltage of a selected cell is lower than a reading level, the selected cell is turned to an On state. For this reason, a cell current flows to the source line SRC from the bit line BL in the path of the transistors 13, 11 and 10 from the capacitor element 20, and thus the node SEN is discharged such that a potential of the node SEN decreases. On the other hand, if a threshold voltage of the selected cell is higher than the reading level, the selected cell is turned to an Off state. For this reason, the node SEN is not discharged, and nearly maintains an initial potential.

Successively, the strobe signal STB is turned to an “L” level, and thus read data is received by the latch circuit SDL. Specifically, if a potential of the node SEN is in an “H” level, the transistor 17 is turned off, and the latch circuit SDL is maintained in an “L” level in an initial state. On the other hand, if a potential of the node SEN decreases, the transistor 17 is turned on, and the latch circuit SDL is maintained in an “H” level.

### Bit Line Shield Type Reading Operation

Next, with reference to (a) of FIG. 5, the bit line shield type reading operation will be described.

First, for example, if a reading target bit line is an odd-numbered bit line, the latch circuit SDL connected to the odd-numbered bit line is reset such that the node INV_S is set to an “L” level. In addition, in the latch circuit SDL connected to the even-numbered bit line, the node INV_S thereof is set to an “H” level.

Next, the signals BLS, BLC, BLX and HLL are turned to an “H” level, and the signal XXL is turned to an “L” level.

In the sense amplifier portion SA connected to the odd-numbered bit line BL which is a reading target, since the node INV_S is in an “L” level, the bit line BL is charged in the path of the transistors 19, 12, 11 and 10, and the capacitor element 20 is charged in the path of the transistors 19 and 14. When the bit line is charged, the signal BLC is set to, for example, (0.5 V+Vth) (where Vth is a threshold voltage of an n channel MOS transistor).

In addition, in the sense amplifier portion SA connected to the even-numbered bit line BL, the node INV_S is in an “H” level. For this reason, the transistor 19 is turned off, thus the bit line BL and the capacitor element 20 are not charged, and the bit line BL functions as a shield line.

Successively, the signals BLC, BLX and HLL are turned to an “L” level.

Here, if a threshold voltage of the selected cell connected to the odd-numbered bit line which is a reading target is higher than a reading level, the selected cell is in an Off state, and the bit line BL is maintained in an “H” level. In addition, if a threshold voltage of the selected cell is lower than the reading level, the selected cell is turned to an On state, and electric charge of the bit line BL is released. For this reason, the bit line BL is turned to an “L” level.

Next, the signal BLC is set to an “H” level again, and thus data of the bit line is sensed. The “H” level of the signal BLC is set to, for example, (0.4 V+Vth) which is slightly lower than the “H” level during charging. If the selected cell is in an On state, the node SEN is in an “L” level, and thus the transistor 17 is turned on. On the other hand, if the selected cell is in an Off state, the node SEN is maintained in an “H” level, and thus the transistor 17 remains turned off.

Next, the strobe signal STB is turned to an “L” level, and thus data is captured by the latch circuit SDL. If the selected cell is in an On state, the transistor 17 is turned on, and thus the node INV_S of the latch circuit SDL is turned to an “H” level. On the other hand, if the selected cell is in an Off state, the transistor 17 is turned off, and thus the node INV_S of the latch circuit SDL is maintained in an “L” level.

In addition, the ABL type or bit line shield type reading operation may be employed in a program verification operation of verifying a threshold voltage of the memory cell after data is written to the memory cell.

### Binary or Quaternary Reading Operation

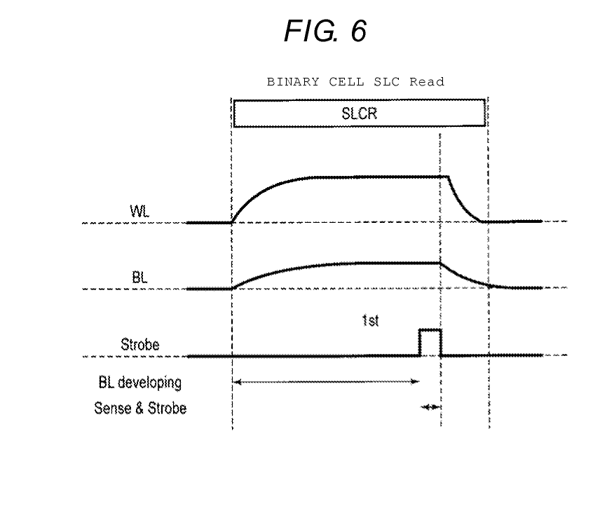

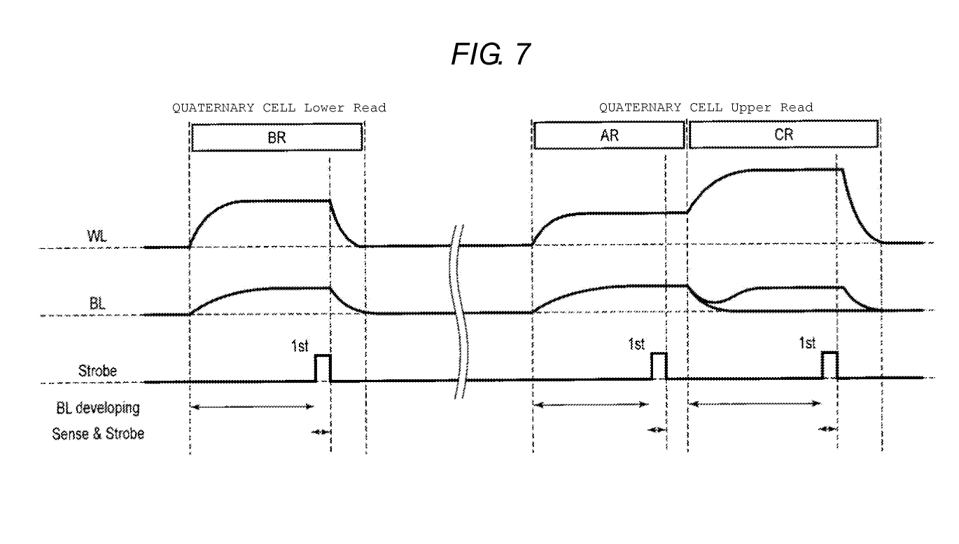

FIG. 6 illustrates an example of reading data from a single level cell (SLC) in which binary data is stored in a single memory cell, and FIG. 7 illustrates an example of reading data from a multilevel cell (MLC) in which, for example, quaternary data is stored in a single memory cell.

Both of the operations of reading binary and quaternary data illustrated in FIGS. 6 and 7 are an example of the ABL type reading operation, and an operation current continuously flows during sensing of data.

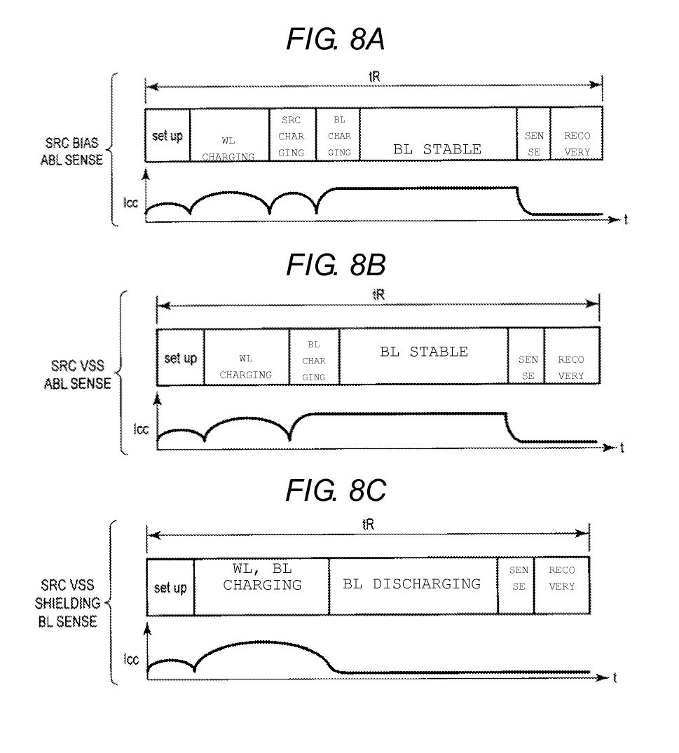

Each of FIGS. 8A, 8B and 8C illustrates a relationship between a sequence and an operation current Icc when a single level illustrated in FIG. 6 is read.

FIG. 8A illustrates a reading time tR in source bias ABL sense (SRC BIAS ABL SENSE) in which the source line is biased to a positive voltage. In this case, the reading time tR mainly includes a setup time which is a starting time of a charge pump circuit (not illustrated), a charging time of the word line (WL), a charging time of the source line (SRC), a charging time of the bit line (BL), a stable time of the bit line (BL), a sense time when a cell current ICELL is actually captured in the sense amplifier, and a recovery time when the word line and the bit line return to initial states.

FIG. 8B illustrates a reading time tR in source VSS ABL sense (SRC VSS ABL SENSE) in which the source line is set to 0 V (VSS). In this case, since the source line is not required to be charged, time of 2 to 3 μs is reduced as compared with the source bias ABL sense illustrated in FIG. 8A. In addition, a voltage to be applied to the word line is shifted and reduced by a reduced level of the source line, and thus a charging time of the word line can also be reduced. However, if the source line is set to VSS, On resistance of a transistor which connects the source line to the power supply VSS or resistance of a power supply line becomes apparent, and thus noise of the source line goes worse than in the source bias ABL sense type.

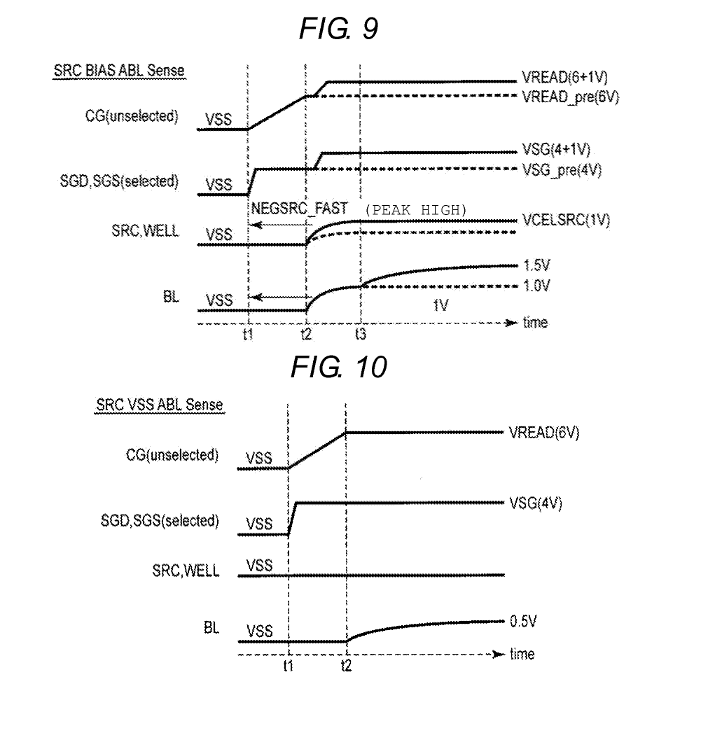

FIG. 9 illustrates a timing of each part in the source bias ABL sense (SRC BIAS ABL SENSE), and FIG. 10 illustrates a timing of each part in the source VSS ABL sense (SRC VSS ABL SENSE). The source bias ABL sense illustrated in FIG. 9 needs a charging time t2 to t3 of the source line SRC, but the source VSS ABL sense illustrated in FIG. 10 does not need the charging time of the source line SRC. For this reason, the source VSS ABL sense can further reduce a reading time than the source bias ABL sense.

FIG. 8C illustrates a reading time tR not in ABL sense but in bit line shield type sense (SRC VSS SHIELDING BL SENSE) in which the source line is set to 0 V (VSS). In the above-described ABL sense, a potential of the bit line is required to be constant, and thus a cell current continuously flows from the sense amplifier to the cell via the bit line as the operation current Icc during a stable period of a bit line potential.

In contrast, in a case of the bit line shield type sense, the word line and the bit line are precharged together, then the selection gate is turned on such that electric charge of the bit line is released according to a cell current, and a variation in a voltage is sensed. For this reason, the operation current Icc flows minimally during the discharging time of the bit line as illustrated in FIG. 8C.

The reading time tR in the bit line shield type sense is not greatly different from the reading time in the source VSS ABL sense illustrated in FIG. 8B. However, in the bit line shield type sense, a potential of the bit line varies, and thus adjacent bit lines are required to be alternately shielded in order to reduce noise. For this reason, as described above, the number of bit lines which can be selected in one-time reading is a half of the number of bit lines. In other words, in the bit line shield type sense, a page length is a half of a page length in the ABL sense.

For this reason, generally, the source bias ABL sense method with less noise of the source line is used in program verification during programming or normal reading.

### Fast Reading Operation

Next, a fast reading operation according to the present embodiment will be described. The present embodiment provides two examples as the fast reading operation.

### EXAMPLE 1

Example 1 uses the source bias ABL sense (a page length is 2N) with less noise of the source line, illustrated in FIG. 9, in program verification during programming, or normal reading. In addition, in fast reading, the source VSS ABL sense in which the source line is set to 0 V (VSS), illustrated in FIG. 10, or, as indicated by the broken line in SRC, WELL of FIG. 9, the source bias ABL sense in which a level of the source line is set to a level (indicated by the broken line in FIG. 9) which is lower than the level VCELSRC (for example, 1 V) in normal reading and higher than 0 V, is used.

According to Example 1, in the fast reading, time required to charge the source line can be reduced, and thus a reading time can be reduced. In the fast reading, a page length may be 2N or 1N. Of course, source line noise can be further reduced at 1N than at 2N. However, the source line noise can be controlled in the present circumstances in which data is required to be randomized, and thus the noise can be sufficiently canceled by correcting a voltage of a selected word line.

### EXAMPLE 2

Example 2 uses the source bias ABL sense (a page length is 2N) with less noise of the source line in program verification during programming, or normal reading. In addition, in the fast reading, not the ABL sense but the bit line shield type sense in which the source line is set to 0 V (VSS) is used. In the fast reading, a page length is 1N.

If the bit line shield sense method is used, a page length in reading becomes a half, but, in a solid state drive (SSD) or the like which originally needs fast reading, random access reading frequently occurs in the unit of a data size of 4 KB. In an existing large capacity NAND type flash memory, a page length is, for example, 8 KB or more, and data can be sufficiently read in the unit of 4 KB by using the bit line shield sense method even if a page length in reading becomes a half. As a matter of fact, if a page length is 4 KB or more, data corresponding to an amount exceeding 4 KB is not necessary in the controller and is thus discarded, and therefore there is no problem in practical use.

In addition, the following effects can be achieved by using not the ABL sense method but the bit line shield sense method. In other words, in a case of the bit line shield sense method, a timing when a current peak occurs in a chip operation is more localized. For this reason, the controller can easily control a peak current by delaying an operation timing of each chip when a plurality of NAND type flash memory chips CP1 and CP2 of the system perform the fast reading operation by using the bit line shield sense method.

For example, in the operation current Icc illustrated in FIG. 8C, the word line, bit line (WL, BL) charging time and the BL discharging time are greatly different from each other in a peak current amount of the operation current Icc. For this reason, the controller can reduce power consumption by controlling a plurality of NAND type flash memory chips CP1 and CP2 so that the peak current amount do not overlap each other.

Specifically, when the NAND type flash memory chip CP1 charges the word line or bit line (WL or BL), the NAND type flash memory chip CP2 performs operations other than the charging of the word line or bit line (WL or BL), and when the NAND type flash memory chip CP1 completes the charging of the word line or bit line (WL or BL), the NAND type flash memory chip CP2 starts charging the word line or bit line (WL or BL), thereby reducing power consumption.

For this reason, in the system, when random data of 4 KB is read at a high speed in parallel and in plurality, the bit line shield sense method is used, and thus the NAND type flash memory chips CP1 and CP2 can be performed together at low current consumption. Therefore, parallelism of the NAND type flash memory chips CP1 and CP2 can be increased, and thus a total throughput can be improved in the data unit of 4 KB.

According to Example 2, not the ABL sense but the bit line shield type sense in which the source line is set to 0 V (VSS) is used in the fast reading, and thus a reading time can be reduced at low current consumption.

### First Example of Three-Dimensional Stacked NAND String

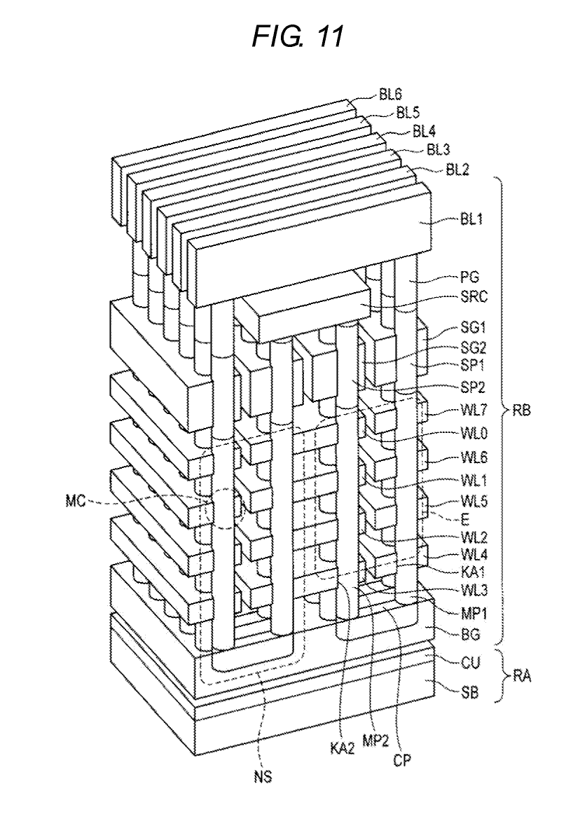

FIG. 11 illustrates the first example of a three-dimensional stacked NAND string.

In FIG. 11, memory cells MC which are stacked in four layers from the bottom are repeatedly formed, and eight memory cells MC are connected in series to each other, thereby forming a NAND string NS. In other words, in the NAND string illustrated in FIG. 11, a current path of a plurality of series-connected memory cells is disposed so as to be perpendicular to the surface of a semiconductor substrate described later. However, the number of memory cells to be stacked, the number of memory cells, and a configuration of the string are not limited thereto.

In FIG. 11, a circuit region RA is provided on a semiconductor substrate SB, and a memory cell region RB is provided on the circuit region RA. In the circuit region RA, a circuit layer CU is formed on the semiconductor substrate SB. In the circuit layer CU, the row decoder 112, the sense amplifier 113, and all or some of circuits forming the peripheral circuit 140, illustrated in FIG. 2, are formed. The memory cell array 111 illustrated in FIG. 2 is formed in the memory cell region RB.

In addition, in the memory cell region RB, the back gate layer BG is formed on the circuit layer CU, and a connection layer CP is formed in the back gate layer BG. Pillar-shaped members MP1 and MP2 are disposed so as to be adjacent to each other on the connection layer CP, and lower ends of the pillar-shaped members MP1 and MP2 are connected to each other via the connection layer CP.

Further, on the connection layer CP, word lines WL3 to WL0 of four layers are sequentially stacked, and word lines WL4 to WL7 of four layers are sequentially stacked so as to be respectively adjacent to word lines WL3 to WL0. The pillar-shaped member MP1 penetrates through the word lines WL4 to WL7, and the pillar-shaped member MP2 penetrates through the word lines WL0 to WL3, thereby forming the NAND string NS.

A pillar-shaped semiconductor forming a channel region which is a current path (not illustrated) is formed at the center of each of the pillar-shaped members MP1 and MP2. A tunnel insulating film, a charge trap layer, and a block insulating film (none illustrated) are sequentially formed around the pillar-shaped semiconductor. The memory cells MC are formed at intersecting positions of the pillar-shaped members MP1 and MP2, the word lines WL0 to WL3, and the word lines WL4 to WL7.

In addition, pillar-shaped members SP1 and SP2 are respectively formed on the pillar-shaped members MP1 and MP2.

A selection gate electrode SG1 through which the pillar-shaped member SP1 penetrates is formed over the word line WL7 located in the uppermost layer, and a selection gate electrode SG2 through which the pillar-shaped member SP2 penetrates is formed over the word line WL0 located in the uppermost layer.

In addition, a source line SRC connected to the pillar-shaped member SP2 is provided over the selection gate electrode SG2, and the bit lines BL1 to BL6 which are connected to the pillar-shaped member SP1 via a plug PG are formed over the selection gate electrode SG1 for each column. The bit lines BL1 to BL6 are respectively connected to sense amplifiers.

For this reason, the above-described source bias ABL sense, source VSS ABL sense, or bit line shield type sense may be used in the NAND type flash memory with the above-described configuration, and thus the above-described Examples 1 and 2 may be employed.

### Second Example of Three-Dimensional Stacked NAND String

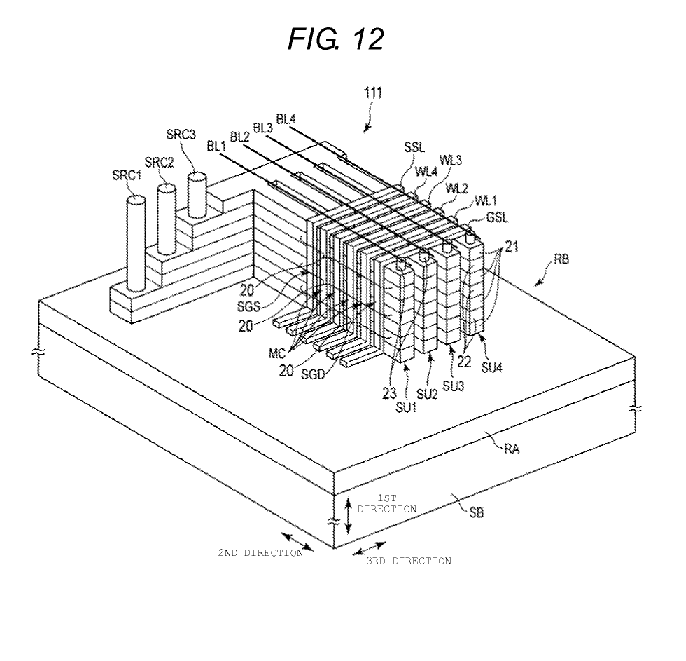

FIG. 12 illustrates a second example of a three-dimensional stacked NAND string.

In the NAND string illustrated in FIG. 12, a current path of a plurality of series-connected memory cells are disposed in parallel to a surface of a semiconductor substrate.

A circuit region RA is provided on a semiconductor substrate SB, and a memory cell region RB is provided on the circuit region RA via an insulating film (not illustrated). In the circuit region RA, the row decoder 112, the sense amplifier 113, and all or some of circuits forming the peripheral circuit 140, illustrated in FIG. 2, are formed. The memory cell array 111 illustrated in FIG. 2 is formed in the memory cell region RB.

The memory cell array 111 includes, for example, four string units SU1 to SU4, and each of the string units SU1 to SU4 includes three stacked NAND strings 20. Each NAND string 20 is formed by a transistor with a so-called fin structure, and includes series-connected four memory cells MC, and first and second selection gates SGD and SGS.

Each of the string units SU1 to SU4 includes, for example, a plurality of insulating films 21 which are alternately stacked on the circuit region RA, a plurality of semiconductor films 22 forming an active region, word lines WL1 to WL4, selection gate lines GSL and SSL, bit lines BL1 to BL4, and source lines SRC1 to SRC3.

The word lines WL1 to WL4, the selection gate line GSL connected to the first selection gate SGD, and the selection gate line SSL connected to the second selection gate SGS are provided in common for the string units SU1 to SU4. In other words, the word lines WL1 to WL4 and the selection gate lines GSL and SSL are formed on side surfaces of the string units SU1 to SU4 via gate insulating films (not illustrated), and each memory cell MC is formed on a side surface of the semiconductor film 22. That is, for example, a MONOS film (not illustrated) is formed between the side surface of the semiconductor film 22 and each of the word lines WL1 to WL4. In each NAND string 20, four memory cells MC are connected in series to each other in the horizontal direction (second direction). Each of the memory cells MC includes a gate insulating film, a charge storage layer, a block insulating film, and a layered gate which has a control gate as a word line (none illustrated).

Further, a bit line contact 23, which is connected in common to the semiconductor films 20 in each string unit, is formed at an end part of each of the string units SU1 to SU4 on the first selection gate SGD side. The bit lines BL1 to BL4 are respectively connected to the bit line contacts 23. The bit lines BL1 to BL4 are respectively connected to sense amplifiers (not illustrated).

For this reason, the above-described source bias ABL sense, source VSS ABL sense, or bit line shield type sense may be used in the NAND type flash memory with the above-described configuration, and thus the above-described Examples 1 and 2 may be employed.

In addition, the source lines SRC1 to SRC3 which are common to the four string units SU1 to SU4 are formed at the end parts of the string units SU1 to SU4 on the second selection gate SGS side. The source line SRC1 is connected to the semiconductor films 20 located in the lowermost layers of the string units SU1 to SU4, the source line SRC2 is connected to the semiconductor films 20 located in the intermediate layers of the string units SU1 to SU4, and the source line SRC3 is connected to the semiconductor films 20 located in the uppermost layers of the string units SU1 to SU4.

In the NAND type flash memory with the above-described configuration, the four string units SU1 to SU4 share the word lines WL, the selection gate line GSL connected to the first selection gate SGD, the selection gate line SSL connected to the second selection gate SGS, and the three NAND strings 20 share the bit line in each string unit. For this reason, the NAND strings 20 are selected by the source lines SRC1 to SRC3.

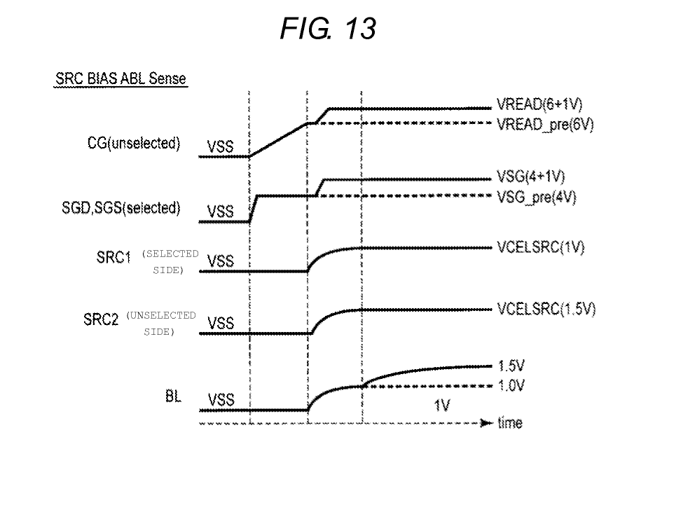

FIG. 13 illustrates an example of an operation of selecting the NAND string 20, for example, in the source bias ABL sense.

For example, if the NAND string 20 connected to the source line SRC1 is selected, the source line SRC1 is set to a so-called normal source level VCELSRC (for example, 1 V). In addition, since the memory strings connected to the source lines SRC2 and SRC3 other than the source line SRC1 are required to be unselected, levels of the source lines SRC2 and SRC3 are set to a level which is the same as a level of the bit line BL, for example, 1.5 V (VCELSRC).

When a voltage VSG is applied to a gate of a selected memory cell, a voltage of the node SEN of the sense amplifier is discharged if the memory cell is in an On state, and the voltage of the node SEN of the sense amplifier is maintained if the memory cell is in an Off state. Accordingly, data of one page can be read.

In the above-described configuration, during fast reading, a voltage of a selected source line is set to 0 V or a voltage in a normal reading operation, for example, a voltage lower than 1 V. For this reason, a charging time of a source line can be reduced, and thus a reading operation can be performed at a high speed.

### Third Example of Three-Dimensional Stacked NAND String

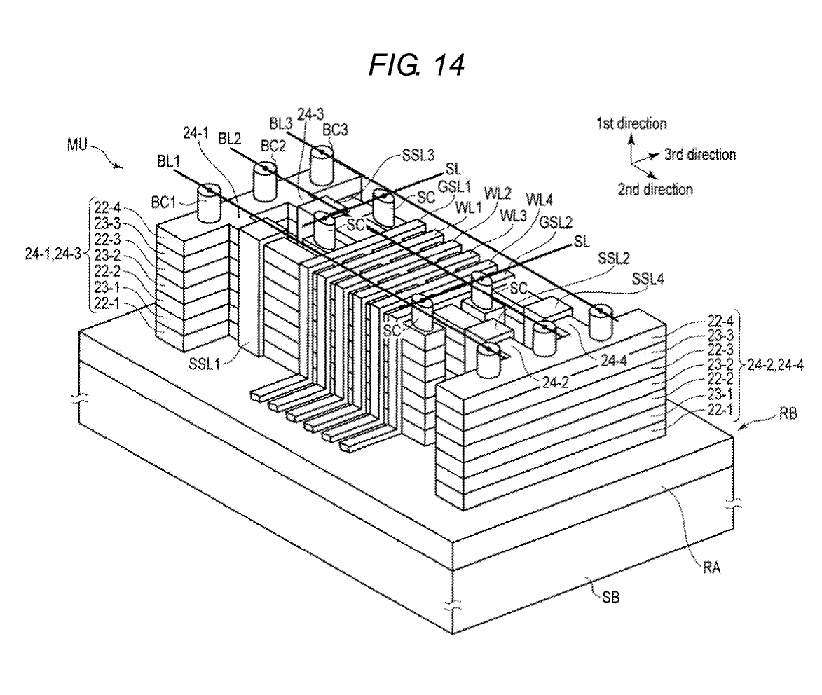

FIG. 14 illustrates the third example of a three-dimensional stacked NAND string.

In the NAND string illustrated in FIG. 14, a current path of a plurality of series-connected memory cells are disposed in parallel to a surface of a semiconductor substrate.

A circuit region RA is provided on a semiconductor substrate SB, and a memory cell region RB is provided on the circuit region RA via an insulating film (not illustrated). In the circuit region RA, the row decoder 112, the sense amplifier 113, and all or some of circuits forming the peripheral circuit 140, illustrated in FIG. 2, are formed. The memory cell array 111 illustrated in FIG. 2 is formed in the memory cell region RB.

FIG. 14 illustrates a single memory unit.

For example, four stripe-shaped string units 24 (24-1 to 24-4) with a fin type structure are formed on an insulating film (not illustrated) on the circuit region RA, and a single memory unit MU is formed by the string units 24 (24-1 to 24-4). The string units 24 (24-1 to 24-4) are disposed in the second direction orthogonal to the first direction which is perpendicular to the surface of the semiconductor substrate SB.

Each of the string units 24 includes insulating films 22 (22-1 to 22-4) and semiconductor layers 23 (23-1 to 23-3), which are alternately stacked in the second direction. A gate insulating film, a charge storage layer, a block insulating film, and a control gate (none illustrated) are sequentially formed on upper surfaces and side surfaces of the string units 24. The charge storage layer is formed of, for example, an insulating film. In addition, the control gate is formed of a conductive film, and functions as word lines WL or selection gate lines GSL1 and GSL2. The word lines WL and the selection gate lines GSL1 and GSL2 are formed so as to cross over a plurality of string units 24. Further, control signal lines SSL1 to SSL4 are formed independently for each string unit 24.

Contact plugs BC1 to BC3 are formed at first end parts of the odd-numbered string units 24-1 and 24-3. The contact plug BC1 connects the semiconductor layer 23-1 of the string units 24-1 and 24-3 to the bit line BL1, and are insulated from the semiconductor layers 23-2 and 23-3. The contact plug BC2 connects the semiconductor layer 23-2 of the string units 24-1 and 24-3 to the bit line BL2, and are insulated from the semiconductor layers 23-1 and 23-3. The contact plug BC3 connects the semiconductor layer 23-3 of the string units 24-1 and 24-3 to the bit line BL3, and are insulated from the semiconductor layers 23-1 and 23-2.

In addition, contact plugs BC1 to BC3 are formed at first end parts of the even-numbered string units 24-2 and 24-4. The contact plug BC1 connects the semiconductor layer 23-1 of the string units 24-2 and 24-4 to the bit line BL1, and are insulated from the semiconductor layers 23-2 and 23-3. The contact plug BC2 connects the semiconductor layer 23-2 of the string units 24-2 and 24-4 to the bit line BL2, and are insulated from the semiconductor layers 23-1 and 23-3. The contact plug BC3 connects the semiconductor layer 23-3 of the string units 24-2 and 24-4 to the bit line BL3, and are insulated from the semiconductor layers 23-1 and 23-2.

In addition, contact plugs SC are formed at second end parts of the string units 24-1 to 24-4. The contact plugs SC are connected to the semiconductor layers 23-1 to 23-3, and the semiconductor layers 23-1 to 23-3 are connected to the source lines SL via the contact plugs SC. As above, in relation to the source lines SL, the source lines SL are connected in common to four string units 24-1 to 24-4 in the same manner as the three-dimensional stacked NAND string illustrated in FIG. 12.

The bit lines BL1 to BL3 are respectively connected to sense amplifiers (not illustrated). For this reason, the above-described source bias ABL sense, source VSS ABL sense, or bit line shield type sense may be used in the NAND type flash memory, and thus the above-described Examples 1 and 2 may be employed.

In addition, the NAND type flash memory employs, for example, the source bias ABL sense during fast reading. In this case, a relationship between potentials of the respective portions is the same as the waveform illustrated in FIG. 9. In other words, during the fast reading, a voltage (indicated by the broken line in FIG. 9) of a selected source line is set to a voltage lower than the voltage VCELSRC (for example, 1 V) in normal reading and higher than 0 V. For this reason, a charging time of a source line can be reduced, and thus a reading operation can be performed at a high speed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a plurality of memory cells;
a bit line electrically connected to a first end of the memory cells;
a source line electrically connected to a second end of the memory cells; and
a control unit configured to carry out one of first and second sense operations, the first sense operation being carried out when a first read command is received and the second sense operation being carried out when a second read command is received, the first read command being different from the second read command.

2. The device according to claim 1, wherein the source line is electrically connected to ground when the first sense operation is carried out.

3. The device according to claim 2, wherein the source line is electrically connected to a reference voltage source when the second sense operation is carried out.

4. The device according to claim 1, wherein one of the first and second sense operations is carried out during a read operation.

5. The device according to claim 1, wherein one of the first and second sense operations is carried out during a write operation.

6. The device according to claim 1, further comprising:
a plurality of bit lines electrically connected to the memory cells, wherein all of the bit lines are sensed collectively when the first sense operation is carried out.

7. The device according to claim 1, further comprising:
a plurality of bit lines electrically connected to the memory cells, wherein a first group of the bit lines are sensed collectively and then a second group of the bit lines are sensed collectively, when the first sense operation is carried out.

8. The device according to claim 7, wherein the bit lines in the first group are different from the bit lines in the second group.

9. The device according to claim 1, wherein
the plurality of memory cells are stacked above a semiconductor substrate, and
a current path of the plurality of memory cells connected in series is disposed in a first direction perpendicular to the semiconductor substrate.

10. The device according to claim 1, wherein
the plurality of memory cells are stacked above a semiconductor substrate, and
a current path of the plurality of memory cells connected in series is disposed in a second direction parallel to the semiconductor substrate.

11. A nonvolatile semiconductor memory device comprising:
a plurality of memory cells;
a bit line electrically connected to a first end of the memory cells;
a source line electrically connected to a second end of the memory cells; and
a control unit configured to select one of a first sense operation during which the source line is electrically connected to ground and a second sense operation during which the source line is electrically connected to a reference voltage source, according to a type of command received by the memory device.

12. The device according to claim 11, wherein the command is a read command.

13. The device according to claim 11, wherein the command is a write command.

14. The device according to claim 11, further comprising:
a plurality of bit lines electrically connected to the memory cells, wherein all of the bit lines are sensed collectively when the first sense operation is carried out.

15. The device according to claim 11, further comprising:
a plurality of bit lines electrically connected to the memory cells, wherein a first group of the bit lines are sensed collectively and then a second group of the bit lines are sensed collectively, when the first sense operation is carried out.

16. The device according to claim 15, wherein the bit lines in the first group are different from the bit lines in the second group.

17. The device according to claim 11, wherein
the plurality of memory cells are stacked above a semiconductor substrate, and
a current path of the plurality of memory cells connected in series is disposed in a first direction perpendicular to the semiconductor substrate.

18. The device according to claim 11, wherein
the plurality of memory cells are stacked above a semiconductor substrate, and
a current path of the plurality of memory cells connected in series is disposed in a second direction parallel to the semiconductor substrate.

19. A method of performing a sensing operation in a nonvolatile semiconductor memory device including a plurality of memory cells, a bit line electrically connected to a first end of the memory cells, and a source line electrically connected to a second end of the memory cells, said method comprising:
receiving a command; and
selecting one of a first sense operation during which the source line is electrically connected to ground and a second sense operation during which the source line is electrically connected to a reference voltage source, according to a type of the received command.

20. The method of claim 19, wherein the first sense operation is selected in response to a fast read command and the second sense operation is selected in response to a normal read command.
